(19) United States
(12) Patent Application Publication
(10) Pub. No.: US 2019/0094427 A1
(43) Pub. Date: Mar. 28, 2019

(54) MANUFACTURING METHOD OF DISPLAY PANEL, DISPLAY PANEL ASSEMBLY AND DISPLAY DEVICE

(71) Applicant: Wuhan China Star Optoelectronics Technology Co., Ltd., Wuhan (CN)

(72) Inventor: Xiong CHENG, Shenzhen (CN)

(21) Appl. No.: 15/996,993

(22) Filed: Jun. 4, 2018

Related U.S. Application Data
(63) Continuation of application No. PCT/CN2018/071298, filed on Jan. 4, 2018.

(30) Foreign Application Priority Data
Sep. 26, 2017 (CN) 201710880295.X

(51) Int. Cl. G02B 5/20; G02F 1/1335; H01L 27/146; G02F 1/1333; G02F 1/01

(52) U.S. Cl. CPC G02B 5/20; G02F 1/133514; G02F 2001/133354; G02F 1/133351; G02F 1/0107; H01L 27/14621

(57) ABSTRACT

A display panel assembly is provided, which includes an array substrate and a color filter substrate disposed in aligned cell. The array substrate and the color filter substrate are divided into at least two display regions and cutting regions connecting to two adjacent display regions. Each cutting region has a cutting line, and two display panels are formed by cutting the display panel assembly along the cutting line. The display panel assembly corresponding to each cutting region further includes two supporting structures located between the array substrate and the color filter substrate, the two support structures are respectively located at two sides of the cutting line. By cutting the above display panel assembly, it is possible to reduce the problem of product failure caused by the pressure that cannot be effectively and uniformly output during cutting. A manufacturing method of a display panel and a display device are also provided.

### RELATED APPLICATIONS

This application is a continuation application of PCT Patent Application No. PCT/CN2018/071298, filed Jan. 4, 2018, which claims the priority benefit of Chinese Patent Application No. 201710880295.X, filed Sep. 26, 2017, which is herein incorporated by reference in its entirety.

### FIELD OF THE DISCLOSURE

The disclosure relates to a display panel assembly, a manufacturing method of display panel, and a display device.

### BACKGROUND

With the rapid development of science and technology, the applications of display devices in people's lives are also becoming more and more widespread. Display panels, which are an important part of display devices, are generally obtained by cutting a motherboard of a display panel. However, when the motherboard is cut into separate display panels, the product yield cannot be further improved, resulting in a waste of resources.

### SUMMARY

Accordingly, the present disclosure provides a display panel assembly to solve the above technical problems.

Furthermore, the disclosure further provides a manufacturing method of a display panel by using the above display panel assembly, and a display device including the foregoing display panel.

A display panel assembly comprising an array substrate and a color filter substrate disposed in aligned cell, wherein the aligned cell array substrate and a color filter substrate are divided into at least two display regions and cutting regions connecting two adjacent display regions, each cutting region has a cutting line, at least two display panels are formed by cutting the display panel assembly along the cutting line, and the display panel assembly corresponding to each cutting region further comprises two supporting structures located between the array substrate and the color filter substrate, and the two support structures are respectively located at two sides of the cutting line.

A manufacturing method of a display panel, comprising the steps of: providing a display panel assembly, wherein the display panel assembly comprises an array substrate and a color filter substrate disposed in aligned cell, the aligned cell array substrate and a color filter substrate are divided into at least two display regions and cutting regions connecting two adjacent display regions, each cutting region has a cutting line, each display region is corresponding to one display panel, the display panel assembly corresponding to each cutting region further comprises two supporting structures located between the array substrate and the color filter substrate, and the two support structures are respectively located at two sides of the cutting line; and cutting the display panel assembly along the cutting line in each cutting region to obtain at least two display panels.

A display device comprising a display panel, wherein the display panel is formed by a manufacturing method as follows: providing a display panel assembly, wherein the display panel assembly comprises an array substrate and a color filter substrate disposed in aligned cell, the aligned cell array substrate and a color filter substrate are divided into at least two display regions and cutting regions connecting two adjacent display regions, each cutting region has a cutting line, each display region is corresponding to one display panel, the display panel assembly corresponding to each cutting region further comprises two supporting structures located between the array substrate and the color filter substrate, and the two support structures are respectively located at two sides of the cutting line; and cutting the display panel assembly along the cutting line in each cutting region to obtain at least two display panels.

The display panel assembly of the present disclosure includes at least two display regions and cutting regions connecting with two adjacent display regions. The position of each cutting region corresponding to the cutting line is not provided with a supporting structure, which can reduce poor product problems caused by pressure cannot be effectively and evenly output when cutting the display panel assembly.

### BRIEF DESCRIPTION OF THE DRAWINGS

In order to explain the technical solutions in the embodiments of the present disclosure more clearly, accompanying drawings are for providing further understanding of embodiments of the disclosure. Apparently, the drawings in the description below are merely some embodiments of the disclosure, a person skilled in the art can obtain other drawings according to these drawings without creative efforts.

FIG. 1 is a schematic cross-sectional view of a display panel assembly according to one embodiment of the present disclosure.

FIG. 2 is a partial schematic view a display panel assembly according to one embodiment of the present disclosure.

FIG. 3 is a schematic view of a cutting surface of a display panel formed by cutting various types of display panel assemblies according to the present disclosure.

FIG. 4 is a flowchart of forming a display panel by cutting a display panel assembly according to one embodiment of the present disclosure.

FIG. 5 is a schematic view of a display device having a display panel formed by cutting a panel display assembly according to one embodiment of the present disclosure.

### DETAILED DESCRIPTION OF PREFERRED EMBODIMENTS

The technical solutions in the embodiments of the present disclosure will be described clearly and completely hereinafter with reference to the accompanying drawings in the embodiments of the present invention. Apparently, the described embodiments are merely a part but not all embodiments of the present disclosure. All other embodiments obtained by persons of ordinary skill in the art based on the embodiments of the present disclosure without creative efforts shall fall within the protection scope of the present disclosure.

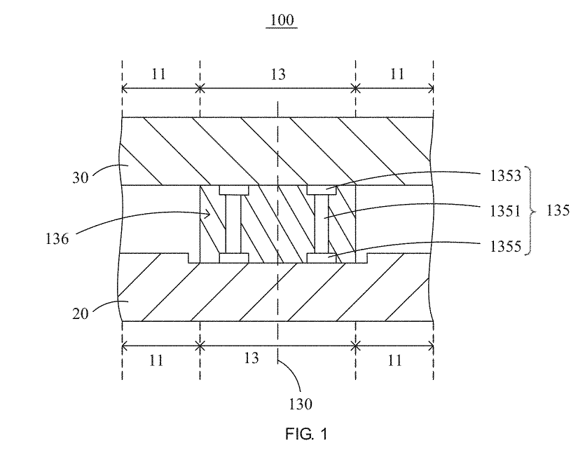

The display panel assembly 100 and the method of forming the display panel 101 according to the present disclosure will be further described in detail below with reference to FIGS. 1 to 4 and the embodiments.

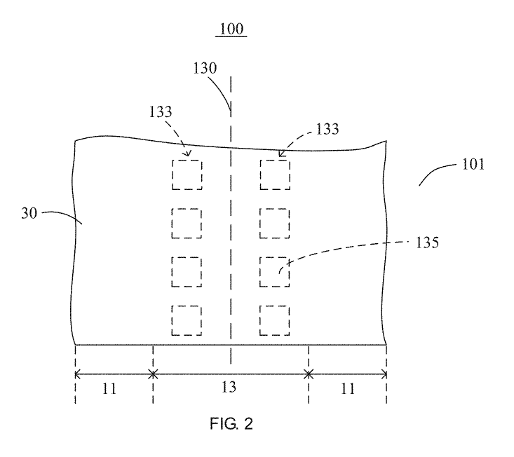

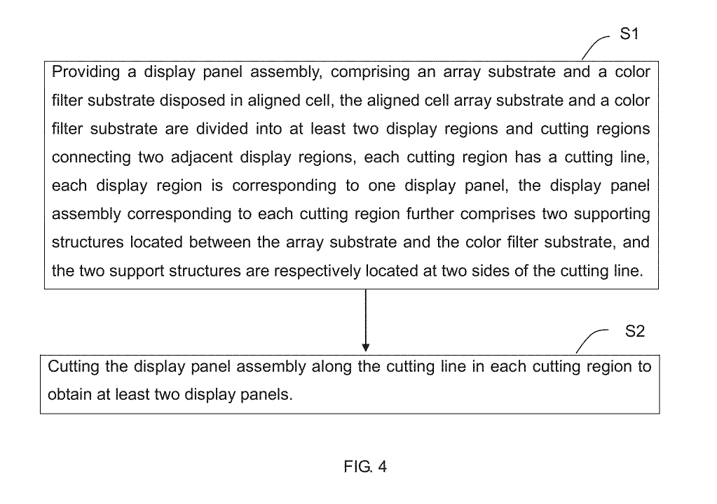

Referring to FIG. 1, FIG. 2 and FIG. 4, a display panel assembly 100 in a preferable embodiment of the present comprises an array substrate 20 and a color filter substrate 30 disposed in aligned cell. The display panel assembly 100 can be cut into at least two display panels 101.

The aligned cell array substrate 20 and a color filter substrate 30 are divided into at least two display regions 11 and cutting regions 13 connecting two adjacent display regions 11. Each cutting region 11 is corresponding to one display panel 101.

Each cutting region 13 has a cutting line 130, at least two display panels 101 are formed by cutting the display panel assembly 100 along the cutting line 130. The display panel assembly 100 is corresponding to each cutting region 13 and further comprises two supporting structures 133 located between the array substrate 20 and the color filter substrate 30, and the two support structures 133 are respectively located at two sides of the cutting line 130. In the embodiment, a distance between central axes of two supporting structures 133 is 130 μm. In other embodiment, the distance between central axes of two supporting structures 133 can be adjusted according to actual needs.

Each of the supporting structures 133 comprises a plurality of supporting body 135 disposed in a direction parallel to the cutting line 130 at intervals.

Each of the supporting body 135 comprises a supporting column 1351 (such as photo spacer), a first supporting portion 1353 and a second supporting portion 1355. The first supporting portion 1353 and the second supporting portion 1355 are respectively located at two sides of the supporting column 1351. The cross-sectional diameters of the first supporting portion 1353 and the second supporting portion 1355 are greater than a cross-sectional diameter of the supporting column 1351.

Each of the supporting body 135 supports the color filter substrate 30 through the first supporting portion 1353, and supports the array substrate 20 through the second supporting portion 1355.

In the present embodiment, a cross-section surface of the supporting column 1351 along the direction parallel to the array substrate 20 is a square with a side length of 20 μm, and a distance between two adjacent supporting column 1351 is 50 μm. The supporting surface of first supporting portion 1353 which supports the color filter substrate 30 is a square with a length of 40 μm. The supporting surface of second supporting portion 1355 which supports the array substrate 20 is a square with a length of 40 μm. And, the distance between two adjacent first supporting portions 1353 or between two adjacent second supporting portions 1355 is 30 μm. In other embodiments, the shape, the size and the spacing of the supporting column 1351, the first supporting portion 1353 and the second supporting portion 1355 can be adjusted according to actual needs.

In the present embodiment, a height of the second supporting portion 1355 in a stacking direction of the array substrate 20 and the color filter substrate 30 is 2.5 μm. In other embodiments, the height of the second supporting portion 1355 can be adjusted according to actual needs.

The display panel assembly 100 further comprises a sealant 136 formed between the array substrate 20 and the color filter substrate 30 corresponding to each cutting region 13, and the sealant covers the supporting structure 133.

A display panel 101 formed by cutting the above display panel assembly 100 comprises the following steps of:

S1, providing a foregoing display panel assembly 100, and dividing it into at least two display regions 11 and cutting regions 13 connecting two adjacent display regions 11. Each cutting region 13 has a cutting line 130.

S2, cutting the display panel assembly 100 along the cutting line 130 in each cutting region 13 to obtain at least two display panels 101.

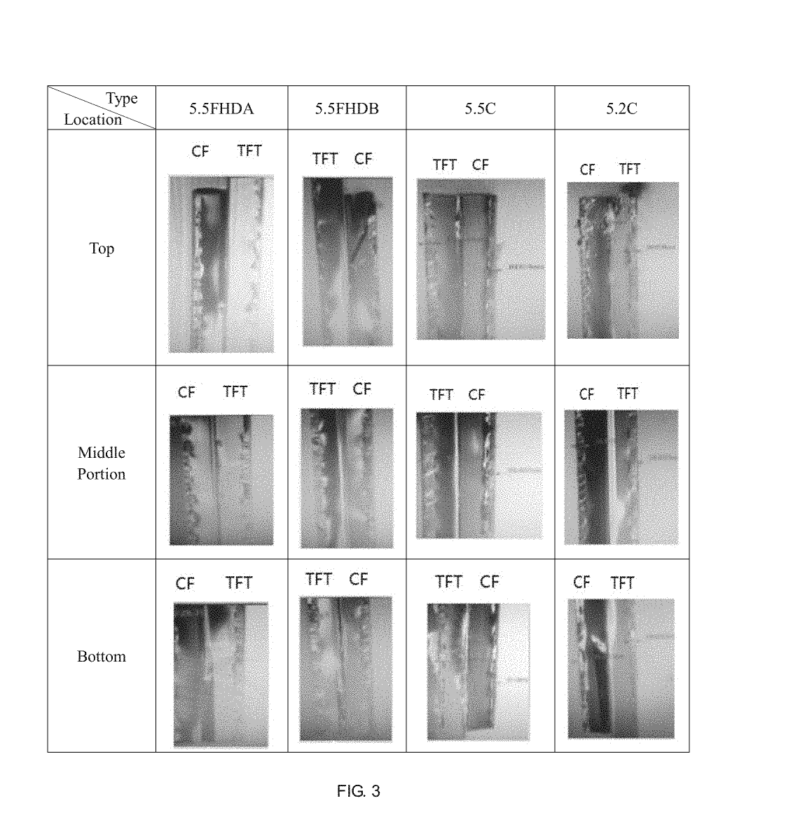

The display panel assemblies of types 5.5FHDA, 5.5FHDB, 5.5C and 5.2C are provided. Each display panel includes four sides of L1, L2, L3 and L4 in turn, and L2 indicates the side of the display panel provided with the terminals. Herein, 5.5 and 5.2 respectively represents that each display panel of the display panel assembly is 5.5 inches in size and 5.2 inches in size. Each of the display panel assemblies of the types 5.5FHDA, 5.5C and 5.2C includes three side-by-side supporting structures in every cutting regions, each supporting structure is composed of a plurality of spaced photo reactive photo spacers, and each supporting structure is disposed corresponding to the cutting line, the remaining two supporting structures are respectively located on both sides of the cutting line. The display panel assembly of type 5.5FHDB is the display panel assembly 100 of the preferred embodiments, in the display panel assemblies of types 5.5FHDA and 5.5FHDB, there are no two display panels with L4 and L4 connection, and the display panel assemblies of types 5.5C and 5.2C have two display panels with L4 and L4 connection. Except for the differences described above, the display panel assemblies of the types 5.5FHDA, 5.5FHDB, 5.5C and 5.2C in other structures are the same. Herein, the above four types of display panel assemblies are cut, and the input amount of the display panel assemblies and the cut line yield after the cutting and the subsequent processes are completed as Table 1, the scrapped amount and scrapped rates on each side of the array substrate (TFT) and the color filter substrate (CF) after cut are shown as Table 2. In addition, the cutting strength of the above four types of display panel assemblies are detected as Table 3. The structure diagrams in each region of the cutting plane of L1 or L3 of the array substrate and L1 or L3 of the color filter substrate of the display panel obtained by the above mentioned four types of display panel assemblies are shown in FIG. 3 (near the top of L4, the terminal close to L2, and at the top and the middle between the terminals).

TABLE 1

| | Type | | | |
|---|---|---|---|---|
| Parameter | 5.5FHDA | 5.5FHDA | 5.5C | 5.2C |
| Input/Piece | 24970 | 18986 | 18102 | 18383 |
| Cut Line yield | 99.77% | 99.78% | 99.37% | 99.25% |

TABLE 2

| | Type | | | |
|---|---|---|---|---|
| Parameter | 5.5FHDA | 5.5FHDA | 5.5C | 5.2C |
| CF-L1/Piece | 189 | 18 | 41 | 47 |
| CF-L3/Piece | 15 | 11 | 47 | 39 |
| CF-L4/Piece | 3 | 1 | 58 | 55 |
| TFT-L1/Piece | 11 | 6 | 31 | 18 |
| TFT-L3/Piece | 140 | 16 | 45 | 19 |
| TFT-L4/Piece | 101 | 12 | 128 | 95 |
| Input/Piece | 24970 | 18986 | 18102 | 18383 |
| Cuttings | 1.84% | 0.34% | 1.93% | 1.49% |
| crapped rate | | | | |

TABLE 3

Type

| Parameter | 5.5FHDA | 5.5FHDA | 5.5C | 5.2C |
|---|---|---|---|---|
| Strength/MPa | 115 | 114 | 108 | 109 |
| Strain/με | 1805 | 1942 | 1905 | 1775 |

From the above data, it can be seen that compared with the display panel assemblies of the types 5.5FHDA, 5.5C and 5.2C, the product yield of the display panel assembly 100 (5.5FHDB) provided by the preferred embodiment of the present disclosure has higher product yield when being cut into display panels, and the cutting strength of the display panel assembly 100 (5.5FHDB) in the present embodiment compared with those display panel assemblies of the types 5.5FHDA, 5.5C, and 5.2C does not change much.

The display panel assembly 100 of the present disclosure includes at least two display regions 11 and cutting regions 13 connecting two adjacent display regions 11. Each cutting region 13 has no supporting structure at a position corresponding to the cutting line 130. So as to reduce the problem of the product failure caused by the pressure of the cutter wheel or the split mechanism for cutting the display panel assembly 100 that cannot be effectively and uniformly output. In addition, the cross-sectional diameters of the first supporting portion 1353 and the second supporting portion 1355 located at two ends of the supporting column 1351 in the display panel assembly 100 of the present disclosure are greater than the cross-sectional diameter of the supporting column 1351. So that the array substrate and the color filter substrate can be effectively supported while reducing the supporting structure, and at the same time, the problem of mura (unevenness of brightness) caused by deformation after the sealant 136 is affected by water vapor or the like is avoided. And, further it reduces the problem of product failure caused by the pressure of the cutter wheel or the split mechanism for cutting the display panel assembly 100 that cannot be effectively and uniformly output.

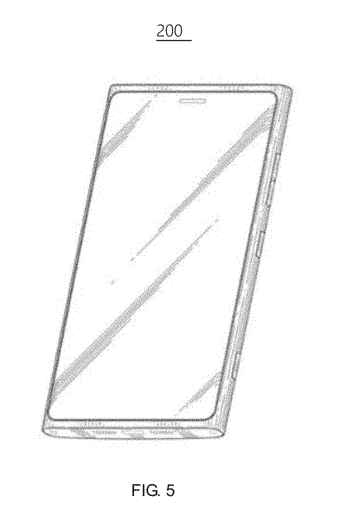

Please refer to FIG. 5, which is a diagram of the display device 200. The display device 200 includes a display panel 101 obtained by a method of forming a display panel as described above. The display device may be a cell phone, a tablet, a television, a display, or the like. The display panel 101 may be a liquid crystal display panel, an OLED display panel, or the like.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A display panel assembly comprising an array substrate and a color filter substrate disposed in aligned cell, wherein the aligned cell array substrate and a color filter substrate are divided into at least two display regions and cutting regions connecting two adjacent display regions, each cutting region has a cutting line, at least two display panels are formed by cutting the display panel assembly along the cutting line, and the display panel assembly corresponding to each cutting region further comprises two supporting structures located between the array substrate and the color filter substrate, and the two support structures are respectively located at two sides of the cutting line.

2. The display panel assembly according to claim 1, wherein the supporting structure comprises a plurality of supporting body disposed in a direction parallel to the cutting line at intervals.

3. The display panel assembly according to claim 2, wherein each of the supporting body comprises a supporting column, a first supporting portion and a second supporting portion, the first supporting portion and the second supporting portion are respectively located at two sides of the supporting column; cross-sectional diameters of the first supporting portion and the second supporting portion are greater than a cross-sectional diameter of the supporting column; the first supporting portion is in contact with the color filter substrate, and the second supporting portion is in contact with the array substrate.

4. The display panel assembly according to claim 1, wherein the display panel assembly further comprises a sealant formed between the array substrate and the color filter substrate corresponding to each cutting region, and the sealant covers each supporting structure.

5. A manufacturing method of a display panel, comprising the steps of:
providing a display panel assembly, wherein the display panel assembly comprises an array substrate and a color filter substrate disposed in aligned cell, the aligned cell array substrate and a color filter substrate are divided into at least two display regions and cutting regions connecting two adjacent display regions, each cutting region has a cutting line, each display region is corresponding to one display panel, the display panel assembly corresponding to each cutting region further comprises two supporting structures located between the array substrate and the color filter substrate, and the two support structures are respectively located at two sides of the cutting line; and
cutting the display panel assembly along the cutting line in each cutting region to obtain at least two display panels.

6. The manufacturing method of a display panel according to claim 5, wherein the supporting structure comprises a plurality of supporting body disposed in a direction parallel to the cutting line at intervals.

7. The manufacturing method of a display panel according to claim 6, wherein each of the supporting body comprises a supporting column, a first supporting portion and a second supporting portion, the first supporting portion and the second supporting portion are respectively located at two sides of the supporting column; cross-sectional diameters of the first supporting portion and the second supporting portion are greater than a cross-sectional diameter of the supporting column; the first supporting portion is in contact with the color filter substrate, and the second supporting portion is in contact with the array substrate.

8. The manufacturing method of a display panel according to claim 5, wherein a distance between central axes of two supporting structures in each cutting region is 130 μm.

9. The manufacturing method of a display panel according to claim 5, wherein the display panel assembly further comprises a sealant formed between the array substrate and the color filter corresponding to each cutting region, and the sealant covers each supporting structure.

10. A display device comprising a display panel, wherein the display panel is formed by a manufacturing method as follows:
providing a display panel assembly, wherein the display panel assembly comprises an array substrate and a color filter substrate disposed in aligned cell, the aligned cell array substrate and a color filter substrate are divided into at least two display regions and cutting regions connecting two adjacent display regions, each cutting region has a cutting line, each display region is corresponding to one display panel, the display panel assembly corresponding to each cutting region further comprises two supporting structures located between the array substrate and the color filter substrate, and the two support structures are respectively located at two sides of the cutting line; and
cutting the display panel assembly along the cutting line in each cutting region to obtain at least two display panels.

11. The display device according to claim 10, wherein the supporting structure comprises a plurality of supporting body disposed in a direction parallel to the cutting line at intervals.

12. The display device according to claim 11, wherein each of the supporting body comprises a supporting column, a first supporting portion and a second supporting portion, the first supporting portion and the second supporting portion are respectively located at two sides of the supporting column; cross-sectional diameters of the first supporting portion and the second supporting portion are greater than a cross-sectional diameter of the supporting column; the first supporting portion is in contact with the color filter substrate, and the second supporting portion is in contact with the array substrate.

13. The display device according to claim 10, wherein a distance between central axes of two supporting structures in each cutting region is 130 μm.

14. The display device according to claim 10, wherein the display panel assembly further comprises a sealant formed between the array substrate and the color filter corresponding to each cutting region, and the sealant covers each supporting structure.
